(19) United States
(12) Patent Application Publication
(10) Pub. No.: US 2026/0305306 A1
(43) Pub. Date: Oct. 1, 2026

(54) PROCESS OPTIMIZED ROUTING FABRIC IN A STACKED DIE

(71) Applicant: Advanced Micro Devices, Inc., Santa Clara, CA (US)

(72) Inventors: Patrick James Shyvers, Fort Collins, CO (US); William Louie Walker, Fort Collins, CO (US)

(73) Assignee: Advanced Micro Devices, Inc., Santa Clara, CA (US)

(21) Appl. No.: 19/094,961

(22) Filed: Mar. 30, 2025

(51) Int. Cl. H10W 20/43; H10B 80/00; H10W 90/00

(52) U.S. Cl. CPC H10W 20/43; H10B 80/00; H10W 90/00

(57) ABSTRACT

In accordance with described techniques for process optimized routing fabric in a stacked die, a stacked dies includes a static random-access memory (SRAM) die, and a compute die in a stacked orientation with the SRAM die. The stacked die also includes a routing fabric implemented on the SRAM die, and the routing fabric processes data routing and distributes the data across the stacked die.

### BACKGROUND

Integrated circuits and/or chips are fabricated on semiconductor material, such as silicon, and include individual semiconductor components, referred to as dies. In one or more variations, a die includes one or more execution units, control units, registers, cache memories, and/or other functional units that enable execution of instructions. Further, the die includes one or more physical communication channels, or interconnects, that facilitate data transfer between the different functional units and components of the die. On-chip networks are used to facilitate the transfer of data via the physical communication channels, or interconnects, to the different functional units and components of the die. An on-chip network includes communication infrastructure integrated onto the die, such as one or more buses, point-to-point connections, or more complex mesh architectures. An on-chip network is also referred to as a network-on-chip (NoC), which is also referred to as an interconnect fabric, a data fabric, a network fabric, or a routing fabric.

### BRIEF DESCRIPTION OF THE DRAWINGS

The detailed description is described with reference to the accompanying figures.

FIG. 1 depicts a block diagram of a processing system configured to execute one or more applications, in accordance with one or more implementations.

FIG. 2 depicts a non-limiting example of a stacked die, as related to process optimized routing fabric in a stacked die as described herein.

FIG. 3 depicts a non-limiting example of a stacked die system, as related to process optimized routing fabric in a stacked die as described herein.

FIG. 4 depicts another non-limiting example of stacked dies, as related to process optimized routing fabric in a stacked die as described herein.

FIG. 5 depicts a procedure in example implementations of process optimized routing fabric in a stacked die, as described herein.

FIG. 6 depicts another procedure in example implementations of process optimized routing fabric in a stacked die, as described herein.

### DETAILED DESCRIPTION

In aspects of the techniques described herein for a process optimized routing fabric in a stacked die, a routing fabric is implemented on a static random-access memory (SRAM) die, rather than being placed on a compute die (also referred to as a transport optimized die) in an integrated circuit chip. A stacked 3D SRAM die with the routing fabric is optimized for data transfer speed, rather than for logic density. This dedicates routing resources for processing on the logic die (e.g., an SRAM die) in high throughput environments, such as in server devices, as well as for GPUs and compute accelerators. An SRAM is a type of volatile memory that stores data without being periodically refreshed, which makes it faster and more reliable for high-performance computing and use in microprocessors, in microcontrollers for cache memory, and in advanced processors that utilize fast-access memory. A compute die is a functional circuit that includes multiple central processing unit (CPU) cores, graphics processing units (GPUs), cache memory, and interconnects.

A stacked die, such as a 3D SRAM die, uses stacking techniques to place SRAM on top of other dies, such as on top of logic dies and compute dies, in an integrated circuit chip. The stacking techniques improve processing performance and reduce power consumption, mainly due to the shorter distances for data transfer between components. The stacking techniques are used to place SRAM closer to the processing cores, which reduces data access times and provides faster performance. The shorter data paths and reduced capacitance of the stacking techniques also provides for lower power consumption.

A routing fabric is also referred to as a network fabric, an on-chip network, or a network-on-chip (NoC), and is implemented in an integrated circuit to transfer data via physical communication channels, interconnects, or wires (also commonly referred to as the metal), to different components and/or locations on compute areas of a die. For example, data is received from off-chip (e.g., from a network or memory) at a corner, edge, or middle of the die by an interface of the on-chip network, and the data is distributed across the compute area of the die. The routing fabric distributes and transfers the data according to a high bandwidth with a low latency.

Conventional processor cores and other semiconductor circuits are implemented on the semiconductor dies. Semiconductor processing and development results in smaller nodes, which are the smallest sized features that can be reliably manufactured. A common challenge is that some aspects of the logic is scaling, while other aspects of the logic is not scaling accordingly, such as due to relative differences between general standard cell logic and SRAM. The metal (e.g., the physical communication channels, interconnects, and/or wires) for data transfer is also not scaling to keep up with transistor designs that are becoming smaller and smaller, and the metal is not getting faster. More wires are being packed in a smaller area for local connectivity between smaller transistor gates, but the metal is not routing the data and signals any faster.

A common approach for developing a new process is to increase performance by packing in more transistors, but an implicit side effect is keeping the die size the same, or approximately the same, and as noted above, the metal is not getting any faster. One challenge that occurs is not being able to transfer long distance data traffic across an integrated circuit chip any faster, or appreciably faster, than with previous circuit implementations. The typical new logic designs that are being added to integrated circuit chips increase connectivity and consume resources on the die. Accordingly, there is a tradeoff between providing sufficient connectivity for the compute logic that is built on these denser processors versus the consistent transfer of data from one side of a chip to the other. Notably, there is a greater demand for local connectivity for data transfer in a stacked 3D die, yet the longer distance connectivity for data transfer across an integrated circuit chip is not improving, which creates a design conflict between providing the sufficient connectivity and being able to transfer data faster.

Accordingly, aspects of this disclosure are directed to using a routing fabric on a stacked 3D SRAM die instead of on the compute die in an integrated circuit chip. A stacked 3D SRAM die with the routing fabric is then optimized for data transfer speed, rather than for logic density. This allows for dedicating the routing resources to process on the logic die, such as in a large SRAM or in an implementation of a high-congestion logic function (e.g., a fused multiply-accumulate (FMAC), a scheduler, etc.). In one or more implementations, aspects of the described process optimized routing fabric in a stacked die is implemented in high throughput environments, such as in server devices, as well as for GPUs and compute accelerators.

In implementations, a NoC (e.g., a packet network, broadcast network, or point-to-point network) has interfaces with the off-chip network, and the interfaces are typically called “on and off ramps” for loading data traffic on and off of the network. Aspects of the described concept for process optimized routing fabric in a stacked die provides for the design and techniques that are implemented to optimize the transit time on the routing fabric (e.g., on the on-chip network). Moving the routing fabric onto the 3D die results in more efficient data transfer processes, and the optimization point for transit changes. The 3D die crossing interface will bisect some area in the routing fabric interface, such as based on design tradeoffs, pin counts between the die, and other design considerations. With the transport layer of the routing fabric moved onto the 3D die, the interface across the SRAM die and the compute die is split, or across the through silicon vias (TSVs), or other interface between the die, taking into consideration how to optimize the metal for the circuit density.

Aspects of the described techniques provides that the 3D die crossing interface can be structured across the entire face of the module or circuit component being connected (e.g., over the entire area of the module or circuit component, rather than just the perimeter), which provides significantly more interconnect. This provides high bandwidth and improved accessibility for data transfer, which also results in improved latency. The data signals can be propagated faster than would otherwise be attainable, and this structure is also beneficial for conserving power compared to most alternatives that move the data traffic off the die. With this structure, it is also easier to maintain synchronous with the logic die (e.g., keeping the dies synchronous with each other in the stacked 3D die arrangement). Aspects of the described techniques also provide scalability for on-chip network bandwidth, and the improved bandwidth provides improved performance of the die.

In some aspects, the techniques described herein relate to a stacked die including an SRAM die, a compute die in a stacked orientation with the SRAM die, and a routing fabric implemented on the SRAM die, the routing fabric configured to process data routing and distribute the data across the stacked die.

In some aspects, the techniques described herein relate to a stacked die, where the routing fabric implemented on the SRAM die is configured for high bandwidth data transfer and low latency to distribute the data across the stacked die.

In some aspects, the techniques described herein relate to a stacked die, where the routing fabric implemented on the SRAM die is configured independent of logic density on the compute die.

In some aspects, the techniques described herein relate to a stacked die, including an on-chip network interface configured to communicate data traffic to and from the routing fabric independent of data transfer delay on the compute die.

In some aspects, the techniques described herein relate to a stacked die, including a routing fabric interface configured for data transfer of the data to and from an off-chip network.

In some aspects, the techniques described herein relate to a stacked die, including a routing fabric interface configured to interface over a surface area of a circuit component of the stacked die.

In some aspects, the techniques described herein relate to a stacked die, including a routing fabric interface configured to interface with the SRAM die and the compute die via a stacked die interface.

In some aspects, the techniques described herein relate to a stacked die, where the routing fabric interface is configured to bisect the stacked die interface based on configuration aspects of the stacked die.

In some aspects, the techniques described herein relate to a stacked die, where the routing fabric interface is configured to bisect with at least a region of the stacked die interface.

In some aspects, the techniques described herein relate to a method including processing data routing by a routing fabric implemented on an SRAM die in a stacked die, the SRAM die configured in a stacked configuration with a compute die, and distributing the data across the stacked die by the routing fabric.

In some aspects, the techniques described herein relate to a method, where the routing fabric implemented on the SRAM die is configured for high bandwidth data transfer and low latency to distribute the data across the stacked die.

In some aspects, the techniques described herein relate to a method, where the routing fabric implemented on the SRAM die is configured independent of logic density on the compute die.

In some aspects, the techniques described herein relate to a method, including communicating data traffic, by an on-chip network interface, to and from the routing fabric independent of data transfer delay on the compute die.

In some aspects, the techniques described herein relate to a method, including interfacing, by a routing fabric interface, over a surface area of a circuit component of the stacked die.

In some aspects, the techniques described herein relate to a method, including interfacing, by a routing fabric interface, with the SRAM die and the compute die via a stacked die interface.

In some aspects, the techniques described herein relate to a method, where the routing fabric interface is configured to bisect with at least a region of the stacked die interface based at least in part on configuration aspects of the stacked die.

In some aspects, the techniques described herein relate to an integrated circuit chip, including a SRAM die, a compute die in a stacked orientation with the SRAM die forming a stacked die, a routing fabric implemented on the SRAM die, the routing fabric configured to process data routing and distribute the data across the stacked die, and a routing fabric interface configured to interface with the SRAM die and the compute die via a stacked die interface.

In some aspects, the techniques described herein relate to an integrated circuit chip, where the routing fabric implemented on the SRAM die is configured for high bandwidth data transfer and low latency to distribute the data across the stacked die.

In some aspects, the techniques described herein relate to an integrated circuit chip, where the routing fabric interface is configured to bisect at least a region of the stacked die interface of the stacked die.

In some aspects, the techniques described herein relate to an integrated circuit chip, further including the stacked die and one or more additional stacked dies, where an additional stacked die includes an SRAM and routing fabric die configured on the compute die.

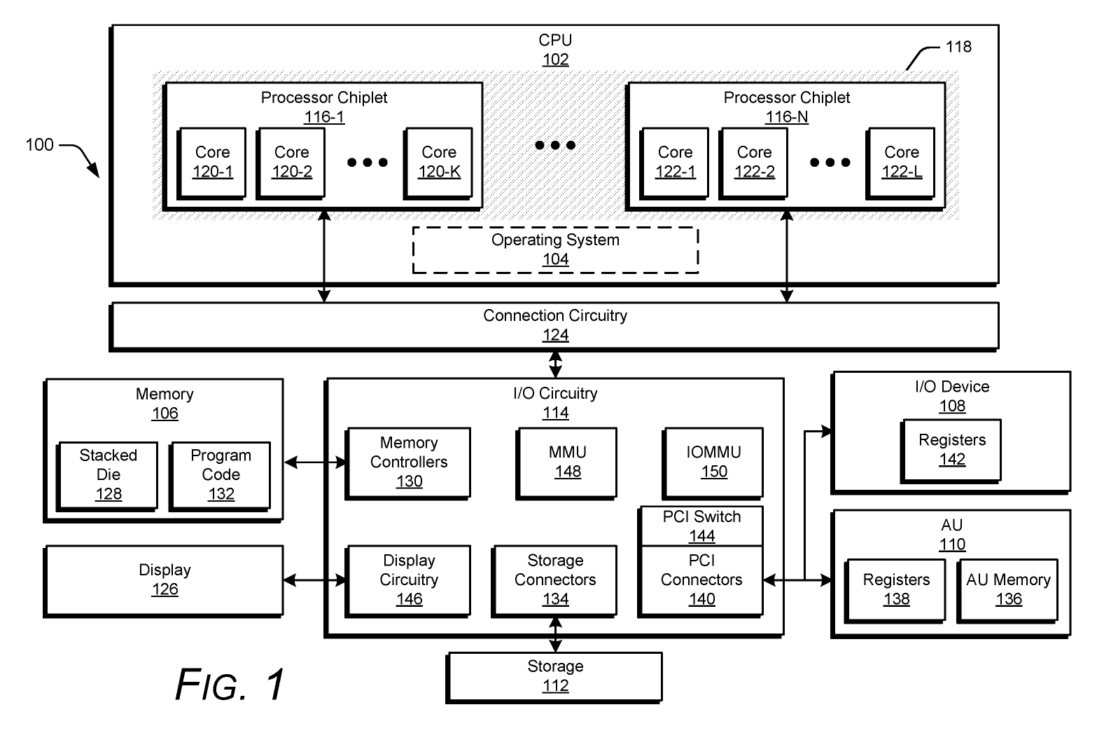

FIG. 1 depicts a block diagram of a processing system 100 configured to execute one or more applications, in accordance with one or more implementations. The processing system 100 is configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 100 includes a central processing unit (CPU) 102. In one or more implementations, the CPU 102 is configured to run an operating system 104 that manages the execution of applications. For example, the operating system 104 is configured to schedule the execution of tasks (e.g., instructions) for applications, allocate portions of resources (e.g., system memory 106, CPU 102, input/output (I/O) device 108, accelerator unit (AU) 110, storage 112, I/O circuitry 114) for the execution of tasks for the applications, provide an interface to I/O devices (e.g., the I/O device 108) for the applications, or any combination thereof.

The CPU 102 includes one or more processor chiplets 116, which are communicatively coupled together by a data fabric 118 in one or more implementations. Each of the processor chiplets 116, for example, includes one or more processor cores 120, 122 configured to concurrently execute one or more series of instructions, also referred to herein as “threads,” for an application. Further, the data fabric 118 communicatively couples each processor chiplet 116-N of the CPU 102 such that each processor core (e.g., processor cores 120) of a first processor chiplet (e.g., 116-1) is communicatively coupled to each processor core (e.g., processor cores 122) of one or more other processor chiplets 116. Though the example implementation presented in FIG. 1 shows a first processor chiplet (116-1) having three processor cores (120-1, 120-2, 120-K) representing a K number of processor cores 122 and a second processor chiplet (116-N) having three processor cores (e.g., 122-1, 122-2, 122-L) representing an L number of processor cores 122 (L being an integer number greater than or equal to one), in other implementations, each processor chiplet 116 may have any number of processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections which are usable to implement data fabric include but are not limited to, buses (e.g., a data bus, a system, an address bus), interconnects, memory channels, through silicon vias, traces, and planes. Other example connections include optical connections, fiber optic connections, and/or connections or links based on quantum entanglement. Additionally, within the processing system 100, the CPU 102 is communicatively coupled to the I/O circuitry 114 by a connection circuitry 124. For example, each processor chiplet 116 of the CPU 102 is communicatively coupled to the I/O circuitry 114 by the connection circuitry 124. The connection circuitry 124 includes, for example, one or more data fabrics, buses, buffers, queues, and the like. The I/O circuitry 114 is configured to facilitate communications between two or more components of the processing system 100, such as between the CPU 102, system memory 106, display 126, universal serial bus (USB) devices, peripheral component interconnect (PCI) devices (e.g., the I/O device 108, the AU 110), storage 112, and the like.

As an example, system memory 106 includes any combination of one or more volatile memories and/or one or more non-volatile memories, examples of which include dynamic random-access memory (DRAM), static random-access memory (SRAM), non-volatile RAM, and the like. In aspects of the described techniques, the system memory 106 is implemented with or as a stacked die 128. In aspects of the described techniques, a routing fabric is implemented on an SRAM die, rather than being placed on a compute die (also referred to as a transport optimized die) in an integrated circuit chip. A stacked 3D SRAM die with the routing fabric is optimized for data transfer speed, rather than for logic density. This dedicates routing resources for processing on the logic die (e.g., an SRAM die) in high throughput environments, such as in server devices, as well as for GPUs and compute accelerators. A stacked die 128, such as a 3D SRAM die, uses stacking techniques to place SRAM on top of other dies, such as on top of logic dies and compute dies, in an integrated circuit chip. The stacking techniques improve processing performance and reduce power consumption, mainly due to the shorter distances for data transfer between components. The stacking techniques are used to place SRAM closer to the processing cores, which reduces data access times and provides faster performance. The shorter data paths and reduced capacitance of the stacking techniques also provides for lower power consumption.

To manage access to the system memory 106 by CPU 102, the I/O device 108, the AU 110, and/or any other components, the I/O circuitry 114 includes one or more memory controllers 130. These memory controllers 130, for example, include circuitry configured to manage and fulfill memory access requests issued from the CPU 102, the I/O device 108, the AU 110, or any combination thereof. Examples of such requests include read requests, write requests, fetch requests, pre-fetch requests, or any combination thereof. That is to say, these memory controllers 130 are configured to manage access to the data stored at one or more memory addresses within the system memory 106, such as by the CPU 102, the I/O device 108, and/or the AU 110.

When an application is to be executed by the processing system 100, the operating system 104 running on the CPU 102 is configured to load at least a portion of program code 132 (e.g., an executable file) associated with the application from, for example, a storage 112 into system memory 106. This storage 112, for example, includes a non-volatile storage such as a flash memory, solid-state memory, hard disk, optical disc, or the like configured to store program code 132 for one or more applications.

To facilitate communication between the storage 112 and other components of processing system 100, the I/O circuitry 114 includes one or more storage connectors 134 (e.g., universal serial bus (USB) connectors, serial AT attachment (SATA) connectors, PCI Express (PCIe) connectors) configured to communicatively couple storage 112 to the I/O circuitry 114, such that I/O circuitry 114 is capable of routing signals to and from the storage 112 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable logic devices (FPGAs)), or any combination thereof.

In at least one example, the AU 110 includes one or more compute units that concurrently execute one or more threads of an application and store data resulting from the execution of these threads in AU memory 136. This AU memory 136, for example, includes any combination of one or more volatile memories and/or non-volatile memories, examples of which include caches, video RAM (VRAM), or the like. In one or more implementations, these compute units are also configured to execute these threads based on the data stored in one or more physical registers 138 of the AU 110.

To facilitate communication between the AU 110 and one or more other components of processing system 100, the I/O circuitry 114 includes or is otherwise connected to one or more connectors, such as PCI connectors 140 (e.g., PCIe connectors) each including circuitry configured to communicatively couple the AU 110 to the I/O circuitry such that the I/O circuitry 114 is capable of routing signals to and from the AU 110 to one or more other components of the processing system 100. Further, the PCI connectors 140 are configured to communicatively couple the I/O device 108 to the I/O circuitry 114 such that the I/O circuitry 114 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 142 of the I/O device 108. In one or more implementations, such physical registers 142 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 140, and one or more other components of the processing system 100, the I/O circuitry 114 includes PCI switch 144. The PCI switch 144, for example, includes circuitry configured to route packets to and from the components of the processing system 100 connected to the PCI connectors 140 as well as to the other components of the processing system 100. As an example, based on address data indicated in a packet received from a first component (e.g., CPU 102), the PCI switch 144 routes the packet to a corresponding component (e.g., AU 110) connected to the PCI connectors 140.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 112, displays the scene on the display 126, or both. The display 126, for example, includes a cathode-ray tube (CRT) display, liquid crystal display (LCD), light emitting diode (LED) display, organic light emitting diode (OLED) display, or any combination thereof. To enable the processing system 100 to display a scene on the display 126, the I/O circuitry 114 includes display circuitry 146. The display circuitry 146, for example, includes high-definition multimedia interface (HDMI) connectors, DisplayPort connectors, digital visual interface (DVI) connectors, USB connectors, and the like, each including circuitry configured to communicatively couple the display 126 to the I/O circuitry 114. Additionally or alternatively, the display circuitry 146 includes circuitry configured to manage the display of one or more scenes on the display 126, such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 114 includes memory management unit (MMU) 148 and input-output memory management unit (IOMMU) 150. The MMU 148 includes, for example, circuitry configured to manage memory requests, such as from the CPU 102 to the system memory 106. For example, the MMU 148 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 148 is configured to translate the virtual address indicated in the memory request to a physical address in the system memory 106 and to fulfill the request. The IOMMU 150 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 138 of the I/O device 108, the registers 138 of the AU 110, and/or the AU memory 136, the CPU 102 issues one or more MMIO requests. Such MMIO requests each request access to read, write, fetch, or pre-fetch data residing at one or more virtual addresses (e.g., guest virtual addresses) which each represent at least a portion of the registers 138 of the I/O device 108, the registers 138 of the AU 110, or the AU memory 136, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 150 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally, or alternatively, in at least one variation, the processing system 100 includes additional and/or different components from those depicted. The processing system 100 is configurable in a variety of ways with different combinations of components in accordance with the described techniques.

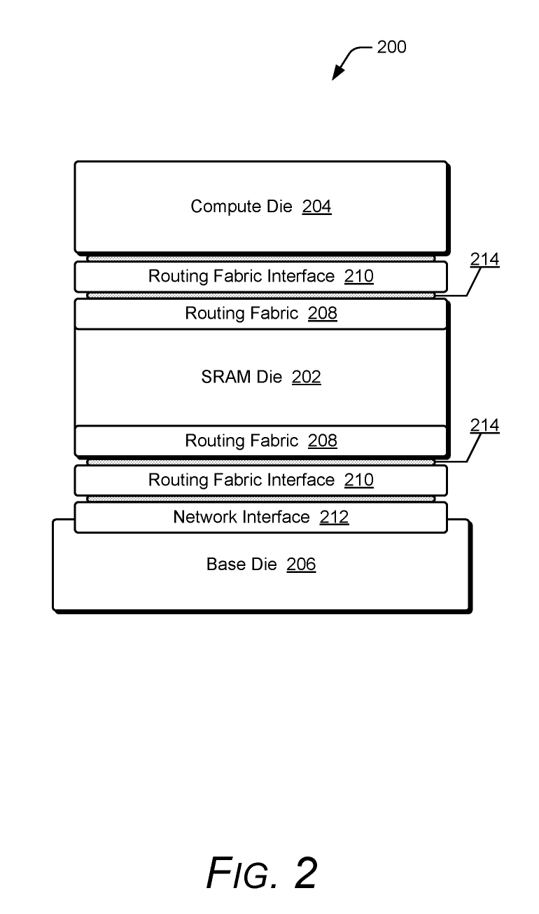

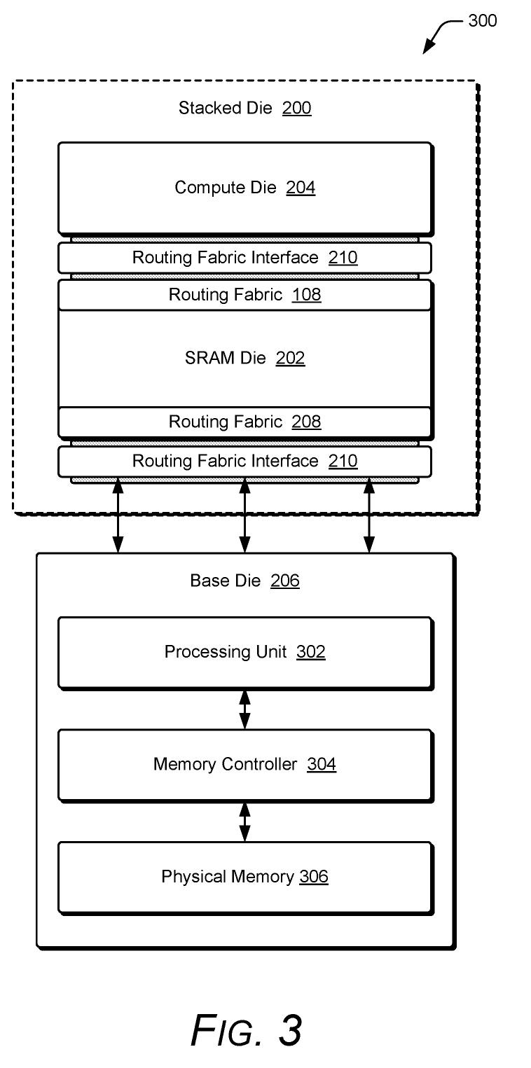

FIG. 2 depicts a non-limiting example of a stacked die 200, as related to process optimized routing fabric in a stacked die as described herein. This example is illustrative of any type of a stacked die that includes a first die and at least a second die on a base die. In one or more implementations, the stacked die 200 is an example of the stacked die 128 shown and described with reference to FIG. 1. This example stacked die 200 includes a SRAM die 202 and the compute die 204 stacked on a base die 206, as well as the routing fabric 208, and a routing fabric interface 210. Additional details, features, and description of the example stacked die 200 and components are as shown and described with reference to FIG. 3.

In one or more implementations, the routing fabric 208 is implemented on the SRAM die 202, rather than being placed on the compute die 204, such as in an integrated circuit chip or semiconductor package that includes the example stacked die 200. The stacked die 200, such as a 3D SRAM die, uses stacking techniques to place the SRAM die 202 on top of (or adjacent to, next to, etc.) other dies. The stacking techniques improve processing performance and reduce power consumption, mainly due to the shorter distances for data transfer between components. The stacking techniques are used to place the SRAM die 202 closer to the processing cores, which reduces data access times and provides faster performance. The shorter data paths and reduced capacitance of the stacking techniques also provides for lower power consumption.

The routing fabric 208 is also referred to as a network fabric, an on-chip network, or a network-on-chip (NoC), and is implemented in an integrated circuit to transfer data via physical communication channels, interconnects, or wires (also commonly referred to as the metal), to the different components and/or locations on the compute areas of the compute die 204. For example, data is received from off-chip (e.g., from a network or memory) at a corner, edge, or middle of the die by a network interface 212 of the on-chip network, and the data is distributed across the compute die. The routing fabric 208 distributes and transfers the data via the routing fabric interface 210 according to a high bandwidth with a low latency.

Aspects of the described concept for process optimized routing fabric in a stacked die provides for the design and techniques that are implemented to optimize the transit time on the routing fabric 208 (e.g., on the on-chip network). Moving the routing fabric 208 onto the SRAM die 202 results in more efficient data transfer processes, and the optimization point for transit changes. A crossing interface of the SRAM die 202 will bisect some area in the routing fabric interface 210, such as based on design tradeoffs, pin counts between the die, and other design considerations. With the routing fabric 208 moved onto the SRAM die 202, the routing fabric interface 210 across the SRAM die 202 and the compute die 204 is split, or across through silicon vias (TSVs), or other interface between the dies, taking into consideration how to optimize the metal for the circuit density.

Aspects of the described techniques provides that the SRAM die 202 crossing interface can be structured across the entire face of a module or circuit component being connected (e.g., over the entire area of the module or circuit component, rather than just the perimeter), which provides significantly more interconnect. This provides high bandwidth and improved accessibility for data transfer, which also results in improved latency. The data signals can be propagated faster than would otherwise be attainable, and this structure is also beneficial for conserving power compared to most alternatives that move the data traffic off the die. With this structure, it is also easier to maintain synchronous with the logic die (e.g., keeping the dies synchronous with each other in the stacked 3D die arrangement). Aspects of the described techniques also provide scalability for on-chip network bandwidth, and the improved bandwidth provides improved performance of the die.

In one or more implementations, the routing fabric 208 that is implemented on the SRAM die 202 is configured for high bandwidth data transfer and low latency to distribute the data across the stacked die 200. Additionally, the routing fabric 208 implemented on the SRAM die 202 is independent of logic density on the compute die 204. Further, an on-chip network interface (e.g., network interface 212) communicates data traffic to and from the routing fabric 208 independent of data transfer delay on the compute die. The routing fabric interface 210 is implemented for data transfer of the data to and from the off-chip network.

In one or more implementations, the routing fabric interface 210 interfaces over a surface area of a circuit component of the stacked die. The routing fabric interface 210 also interfaces with the SRAM die 202 and the compute die 204 via a stacked die interface 214. The routing fabric interface 210 bisects with at least a region of the stacked die interface 214, and the routing fabric interface 210 bisects the stacked die interface 214 based on configuration aspects of the stacked die.

FIG. 3 depicts a non-limiting example of a stacked die system 300, as related to process optimized routing fabric in a stacked die as described herein. The stacked die 200 and/or the base die 206 include one or more functional units, including a processing unit 302, a memory controller 304, and physical memory 306 (e.g., volatile or nonvolatile memory) that are communicatively coupled, one to another. The stacked die 200 and/or the base die 206 are configurable for implementation in a device, such as a computing device, server, mobile device (e.g., wearable, mobile phone, tablet, laptop), a processor (e.g., graphics processing unit, central processing unit, and accelerator), a digital signal processor, disk array controller, hard disk drive host adapter, memory card, solid-state drive, wireless communications hardware connection, Ethernet hardware connection, a switch, bridge, network interface controller, and other apparatus configurations. It is to be appreciated that in various implementations, the device is configured as any one or combination of the listed devices.

In one or more implementations, during a manufacturing process of a processor and/or a memory, a semiconductor material is split into individual semiconductor components, referred to as the dies (e.g., the stacked die 200, the SRAM die 202, the compute die 204, and/or the base die 206). In variations, the stacked die 200 and/or the base die 206 are configured to implement aspects of a memory and/or a processor. By way of example, the stacked die 200 and/or the base die 206 include circuitry configured to store and access data and/or execute instructions. The circuitry includes one or more transistors and/or switches arranged to implement functionality of the processing unit and/or the physical memory 306. The circuitry is arranged and also applied using logic (e.g., steering logic) that enables the stacked die 200 and/or the base die 206 to carry out the functionalities described herein.

The stacked die 200 and/or the base die 206 include one or more execution units, control units, registers, cache memories, and other functional units that enable execution of instructions. Execution units are functional components within a processor that perform types of operations, including arithmetic operations, logic operations, and/or operations related to data movement. Example execution units include, but are not limited to, an arithmetic logic unit (ALU) for performing basic arithmetic, a floating-point unit (FPU) for performing floating-point arithmetic operations, a load-store unit for loading data from memory into registers and storing data from registers back to memory, and a memory management unit to translate virtual addresses to physical addresses for memory access and management, to name just a few. A control unit (e.g., the processing unit 302, the memory controller 304, and/or a unit communicatively coupled with the memory controller 304 or the processing unit 302) manages the execution of instructions, directs flow of data, and coordinates operations within the stacked die 200 and/or the base die 206. For example, a control unit manages execution of instructions retrieved from memory, including decoding the instructions and controlling the flow of data in response to the instructions between different components of the stacked die 200 and/or the base die 206.

In one or more implementations, the physical memory 306 includes one or more registers and/or one or more cache memories. The memory controller 304 of the stacked die 200 and/or the base die 206 utilizes registers to store and access data that is actively being processed or manipulated. Additionally, or alternatively, the stacked die 200 and/or the base die 206 utilize one or more cache memories (e.g., multiple level cache memory) to store and access frequently utilized data.

The stacked die 200 and/or the base die 206 are manufactured from a substrate layer (e.g., made from silicon) and include electronic circuits that performs various operations on and/or using data in the physical memory 306. Examples of the stacked die 200 include, but are not limited to, a central processing unit (CPU), a graphics processing unit (GPU), a field programmable gate array (FPGA), an accelerator, an accelerated processing unit (APU), and a digital signal processor (DSP), to name a few. The processing unit 302, also referred to as a core, reads and executes instructions (e.g., of a program), examples of which include to add, to move data, and to branch. In variations, the processing unit 302 includes, or is configured to implement, one or more switches for routing or moving data. Although one processing unit 302 is depicted in the illustrated example, in variations, the stacked die 200 and/or the base die 206 include more than one processing unit 302 (e.g., a multi-core processor).

The dies representing the different layers of a stack for a 3D architecture and/or a die in a 2D architecture are configured to implement functionality of a processor and/or a memory by utilizing communication channels, such as interfaces in this example. The communication channels are components of the stacked die system 300 that facilitate transfer of data between components of a die for the 3D SRAM architecture. For example, the communication channels provide for routing data between the processing unit 302, the memory controller 304, and/or the physical memory 306, as well as between other components of the stacked die 200 and the base die 206. Example communication channels include, but are not limited to, TSVs when transferring data between layers and/or memory channels, buses (e.g., a data bus), interconnects, traces, or planes within a die to move data to different destinations or components of the die. The stacked die 200 and/or the base die 206 include communication channels disposed within the stacked die 200 and the base die 206, respectively.

In variations, the communication channels are part of an on-chip network that includes one or more switches to enable routing of data packets between components, communication channels, buffers for temporarily storing data packets, and routing logic or steering logic to determine a path for data packets to transfer from an initial destination to a target destination, among other features. In one or more examples, the steering logic includes or is implemented in computer software and/or computer hardware, such as using logic gates, in processor architecture, and/or a computer program.

On-chip networks are used to transfer data via the communication channels, or wires, to different components and/or destinations on compute areas of a die. For example, data is received from off-chip (e.g., from network or memory) to a corner, edge, or middle of the die, and the data is distributed across the compute area of the die by an interface of the on-chip network using the steering logic. The on-chip network is configured to distribute the data according to a high bandwidth with a low latency. In variations, a high bandwidth (e.g., a threshold bandwidth) is defined by a threshold value for an amount of data routed over communication channels during an interval of time (e.g., time period or duration). A low latency (e.g., a threshold latency) is defined by a transmission time period for the data. A transmission time period for the data is an elapsed time period over which the data is transmitted from an initial destination to a final destination. As transistor size has scaled down, the wires that create the physical channels for the data to move across the die have not scaled to match. Thus, in variations, there is an insufficient numerical quantity of wires relative to a volume of data being transferred across the die, which reduces the bandwidth of the on-chip network. To improve the bandwidth, the size of the wires is reduced. However, smaller wires have inferior latency relative to larger wires, causing delays and performance degradation.

To improve bandwidth and/or latency without the tradeoff, an on-chip network is expanded to optionally include the routing fabric 208 implemented on the SRAM die 202. The on-chip network also includes communication channels disposed within the base die 206 and/or the stacked die 200 for transporting data to a destination across the base die 206 and the stacked die 200, respectively. Additionally, or alternatively, the base die 206 and/or the stacked die 200 include communication channels disposed within the base die 206 and/or the stacked die 200 directed towards a coupling location (e.g., routing fabric interface 210) between the stacked die 200 and the base die 206. The coupling location is a point where the stacked die 200 couples to the base die 206. Although communication channels between the stacked die 200 and the base die 206 are depicted as being separate from the stacked die 200 and the base die 206, in one or more implementations, the communication channels are disposed within the stacked die and/or the base die.

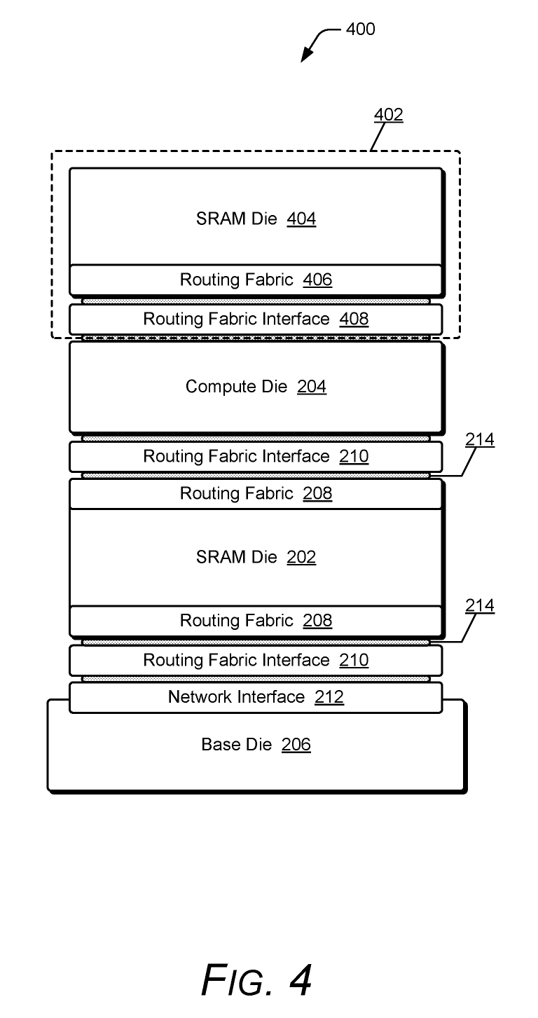

FIG. 4 depicts another non-limiting example 400 of stacked dies, such as related to aspects of process optimized routing fabric in a stacked die as described herein. In one or more implementations, an integrated circuit chip is configurable for implementation with multiple stacked dies in any number of permutations of additional routing fabric, memory storage, and a compute die in an arbitrary height stack of dies. As shown and described with reference to FIG. 2, the example stacked die 200 includes the SRAM die 202 and the compute die 204 stacked on the base die 206, as well as the routing fabric 208, and the routing fabric interface 210 (or routing fabric interfaces). Additionally, this example 400 of the stacked dies, such as in an integrated circuit chip, is illustrative of multiple stacked dies in any number of configurations. This example 400 includes the stacked die 200 with another SRAM and routing fabric die 402 stacked on the compute die 204. The SRAM and routing fabric die 402 includes another SRAM die 404 and additional routing fabric 406, as well as an additional routing fabric interface 408.

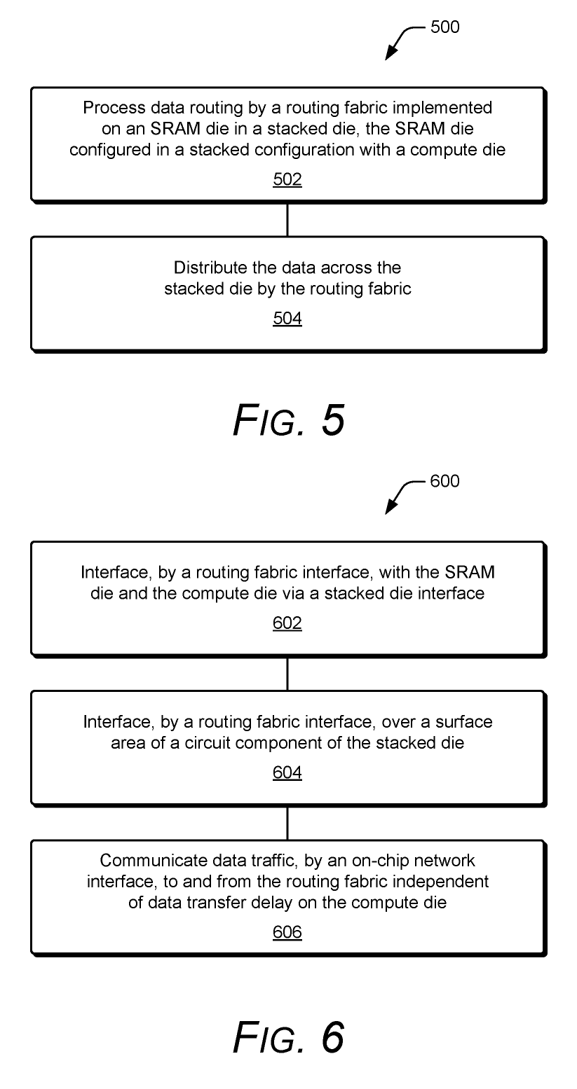

FIG. 5 is a flow diagram depicting a procedure 500 in an example implementation of process optimized routing fabric in a stacked die, as described herein. The order in which the procedure is described is not intended to be construed as a limitation, and any number or combination of the described operations are performed in any order to perform the procedure, or an alternate procedure.

In the procedure 500, data routing is processed by a routing fabric implemented on an SRAM die in a stacked die, the SRAM die configured in a stacked configuration with a compute die (at 502). For example, the stacked die 200 includes the SRAM die 202 and the compute die 204. The stacked die 200 also includes the base die 206, and the routing fabric 208, as well as the routing fabric interface 210. Data is distributed across the stacked die by the routing fabric (at 504). For example, the routing fabric 208 distributes or transfers data across the stacked die 200.

FIG. 6 is a flow diagram depicting a procedure 600 in an example implementation of process optimized routing fabric in a stacked die, as described herein. The order in which the procedure is described is not intended to be construed as a limitation, and any number or combination of the described operations are performed in any order to perform the procedure, or an alternate procedure.

In the procedure 500, a routing fabric interface interfaces with the SRAM die and the compute die via a stacked die interface (at 602). For example, the routing fabric interface 210 interfaces with the SRAM die 202 and the compute die 204 via a stacked die interface 214. The routing fabric interface interfaces over a surface area of a circuit component of the stacked die (at 604). For example, the routing fabric interface 210 interfaces over a surface area of a circuit component of the stacked die 200. Data traffic is communicated, by an on-chip network interface, to and from the routing fabric independent of data transfer delay on the compute die (at 606).

The various functional units illustrated in the figures and/or described herein (including, where appropriate, the stacked die 200, the SRAM die 202, the compute die 204, the base die 206, the routing fabric 208, and the routing fabric interface 210) are implemented in any of a variety of different forms, such as in hardware circuitry, software, and/or firmware executing on a programmable processor, or any combination thereof. The procedures provided are implementable in any of a variety of devices, such as a general-purpose computer, a processor, a processor core, and/or an in-memory processor. Suitable processors include, by way of example, a general purpose processor, a special purpose processor, a conventional processor, a digital signal processor (DSP), a graphics processing unit (GPU), a parallel accelerated processor, a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

In one or more implementations, the methods and procedures provided herein are implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Although implementations of process optimized routing fabric in a stacked die have been described in language specific to features, elements, and/or procedures, the appended claims are not necessarily limited to the specific features, elements, or procedures described. Rather, the specific features, elements, and/or procedures are disclosed as example implementations of process optimized routing fabric in a stacked die, and other equivalent features, elements, and procedures are intended to be within the scope of the appended claims. Further, various different examples are described herein and it is to be appreciated that many variations are possible and each described example is implementable independently or in connection with one or more other described examples.

What is claimed is:

1. A stacked die, comprising:
a static random-access memory (SRAM) die;
a compute die in a stacked orientation with the SRAM die; and
a routing fabric implemented on the SRAM die, the routing fabric configured to process data routing and distribute the data across the stacked die.

2. The stacked die of claim 1, wherein the routing fabric implemented on the SRAM die is configured for high bandwidth data transfer and low latency to distribute the data across the stacked die.

3. The stacked die of claim 1, wherein the routing fabric implemented on the SRAM die is configured independent of logic density on the compute die.

4. The stacked die of claim 1, further comprising an on-chip network interface configured to communicate data traffic to and from the routing fabric independent of data transfer delay on the compute die.

5. The stacked die of claim 1, further comprising a routing fabric interface configured for data transfer of the data to and from an off-chip network.

6. The stacked die of claim 1, further comprising a routing fabric interface configured to interface over a surface area of a circuit component of the stacked die.

7. The stacked die of claim 1, further comprising a routing fabric interface configured to interface with the SRAM die and the compute die via a stacked die interface.

8. The stacked die of claim 7, wherein the routing fabric interface is configured to bisect the stacked die interface based at least in part on configuration aspects of the stacked die.

9. The stacked die of claim 8, wherein the routing fabric interface is configured to bisect with at least a region of the stacked die interface.

10. A method, comprising:
processing data routing by a routing fabric implemented on a static random-access memory (SRAM) die in a stacked die, the SRAM die configured in a stacked configuration with a compute die; and
distributing the data across the stacked die by the routing fabric.

11. The method of claim 10, wherein the routing fabric implemented on the SRAM die is configured for high bandwidth data transfer and low latency to distribute the data across the stacked die.

12. The method of claim 10, wherein the routing fabric implemented on the SRAM die is configured independent of logic density on the compute die.

13. The method of claim 10, further comprising:
communicating data traffic, by an on-chip network interface, to and from the routing fabric independent of data transfer delay on the compute die.

14. The method of claim 10, further comprising:
interfacing, by a routing fabric interface, over a surface area of a circuit component of the stacked die.

15. The method of claim 10, further comprising:
interfacing, by a routing fabric interface, with the SRAM die and the compute die via a stacked die interface.

16. The method of claim 15, wherein the routing fabric interface is configured to bisect with at least a region of the stacked die interface based at least in part on configuration aspects of the stacked die.

17. An integrated circuit chip, comprising:
a static random-access memory (SRAM) die;
a compute die in a stacked orientation with the SRAM die forming a stacked die;
a routing fabric implemented on the SRAM die, the routing fabric configured to process data routing and distribute the data across the stacked die; and
a routing fabric interface configured to interface with the SRAM die and the compute die via a stacked die interface.

18. The integrated circuit chip of claim 17, wherein the routing fabric implemented on the SRAM die is configured for high bandwidth data transfer and low latency to distribute the data across the stacked die.

19. The integrated circuit chip of claim 17, wherein the routing fabric interface is configured to bisect at least a region of the stacked die interface of the stacked die.

20. The integrated circuit chip of claim 17, further comprising the stacked die and one or more additional stacked dies, wherein an additional stacked die comprises an SRAM and routing fabric die configured on the compute die.
